(19) United States
(12) Patent Application Publication
(10) Pub. No.: US 2010/0182093 A1
(43) Pub. Date: Jul. 22, 2010

(54) SINGLE-ENDED TO DIFFERENTIAL CONVERTING APPARATUS AND RF RECEIVING APPARATUS

(75) Inventor: Nobumasa Hasegawa, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 12/750,264

(22) Filed: Mar. 30, 2010

Related U.S. Application Data
(63) Continuation of application No. PCT/JP2007/069190, filed on Oct. 1, 2007.

(51) Int. Cl. H03F 3/50

(52) U.S. Cl. 330/301

(57) ABSTRACT

A single-ended to differential converting apparatus includes a first amplifier configured to output a first voltage signal corresponding to a single phase input signal; and a second amplifier configured to output a second voltage signal corresponding to the first voltage signal, where a first load of the first amplifier, an input transistor of the second amplifier, and a second load of the second amplifier have identical mutual conductance.

### FIELD

The embodiments discussed herein are related to a single-ended to differential converting apparatus and an RF receiving apparatus.

### BACKGROUND

When a single phase signal is input into a circuit that processes a differential signal, the single phase signal is converted into a differential signal. A single-ended to differential converting apparatus performs such conversion.

FIG. 6 is a circuit diagram of a conventional single-ended to differential converting apparatus. As depicted in FIG. 6, single phase input voltage Vᵢₙ is applied at a gate terminal of a first-stage transistor 1. A first output, output voltage Vₒᵤₜ, is acquired at a drain terminal of the first-stage transistor 1. The output voltage Vₒᵤₜ is applied to a gate terminal of a second-stage transistor 2. A second output, output voltage Vₒᵤₜₓ, is acquired from a drain terminal of the second-stage transistor 2. A constant current source 3 is inserted between a source terminal of the first-stage transistor 1 and a ground point, and between a source terminal of the second-stage transistor 2 and the ground point. Load resistors 4 and 5 are inserted between each drain terminal and a positive terminal.

Current corresponding to Vᵢₙ flows through the first-stage transistor 1 and the load resistor 4. Current corresponding to Vₒᵤₜ flows through the second-stage transistor 2 and the load resistor 5. As Vᵢₙ increases, more current flows through the first-stage transistor 1 and the load resistor 4, resulting in lower Vₒᵤₜ. As a result, less current flows through the second-stage transistor 2 and the load resistor 5, increasing Vₒᵤₜₓ. As Vᵢₙ decreases, the opposite phenomenon occurs. Such a differential amplifying circuit receiving single-end signals is disclosed in, for example, Patent Document 1 (Japanese Laid-Open Patent Publication No. 2000-165202, paragraphs [0002], [0003], and [0012]) and Patent Document 2 (Japanese Laid-Open Patent Application Publication No. H10-209773, paragraphs [0003] and [0004]).

FIG. 7 is a circuit diagram of another conventional single-ended to differential converting apparatus. As depicted in FIG. 7, the single-ended to differential converting apparatus includes a pair of inductors 6 and 7. One end of the inductor 6 is grounded and Vᵢₙ is applied to the other end. Vₒᵤₜ and Vₒᵤₜₓ are output from both ends of the inductor 7. This circuit is called balun, which for example is disclosed in Patent Document 1.

However, since the constant current source is coupled to the first-stage and the second-stage transistors in the circuit of FIG. 6, the amplitude of output voltage becomes smaller than the amplitude of source voltage V_{dd} (two-thirds of V_{dd} at maximum), which raises a problem in that the dynamic range of the output voltage may not be widened. Omitting the constant current source may be one countermeasure but a new problem arises. For example, as depicted in FIG. 8, when a single phase input signal is converted to a differential signal by a single-ended to differential converting apparatus 9 in a radio receiving circuit 8, alternating current i_{ac} encounters parasitic inductance 11 of, for example, lines such as a bonding wire between the single-ended to differential converting apparatus 9 and an electrical source 10. Consequently, the ground potential of the single-ended to differential converting apparatus 9 does not become zero and thus, effective mutual inductance decreases and the gain decreases.

On the other hand, in the case of FIG. 7, although the dynamic range of output voltage may be widened, inductor size, about 300 μm×300 μm, is not preferable for integration of a single-ended to differential converting apparatus on an integrated circuit (IC) chip. Further, although the single-ended to differential converting apparatus depicted in FIG. 7 may be made as a component and externally attached to the IC chip, this configuration is not preferable because the number of external components increases and the number of terminals of the IC chip also increases.

### SUMMARY

According to an aspect of an embodiment, a single-ended to differential converting apparatus includes a first amplifier configured to output a first voltage signal corresponding to a single phase input signal; and a second amplifier configured to output a second voltage signal corresponding to the first voltage signal, where a first load of the first amplifier, an input transistor of the second amplifier, and a second load of the second amplifier have identical mutual conductance.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a circuit diagram of a single-ended to differential converting apparatus according to a first embodiment.

FIG. 2 is a circuit diagram of a single-ended to differential converting apparatus according to a second embodiment.

FIG. 3 is a circuit diagram of a single-ended to differential converting apparatus according to a third embodiment.

FIG. 4 is a circuit diagram of a single-ended to differential converting apparatus according to a fourth embodiment.

FIG. 5 is a diagram of an RF receiving apparatus according to a fifth embodiment.

FIG. 6 is a circuit diagram of a conventional single-ended to differential converting apparatus.

FIG. 7 is a circuit diagram of another conventional single-ended to differential converting apparatus.

FIG. 8 is a diagram illustrating a problem associated with conventional single-ended to differential converting apparatuses.

### DESCRIPTION OF EMBODIMENTS

Embodiments will be explained with reference to the accompanying drawings. In the description below and the attached drawings, like reference numerals or symbols are used for like items, and repetitive explanations are omitted. Embodiments described here do not limit the invention.

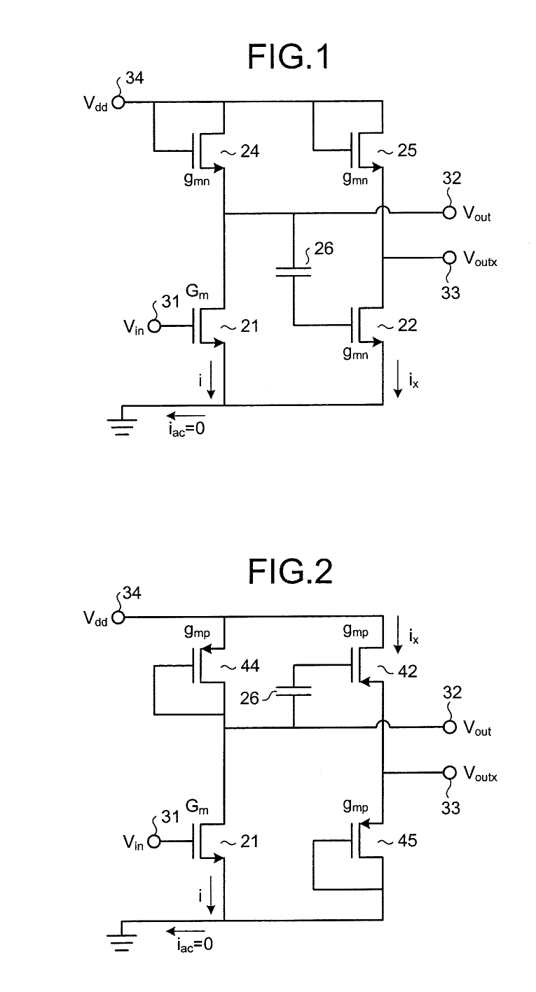

FIG. 1 is a circuit diagram of a single-ended to differential converting apparatus according to a first embodiment. As depicted in FIG. 1, the single-ended to differential converting apparatus includes a first amplifier (hereinafter “first-stage amplifier”) including a first input transistor 21 and a first load 24, and a second amplifier (hereinafter “second-stage amplifier”) including a second input transistor 22 and a second load 25. The first input transistor 21, the second input transistor 22, the first load 24, and the second load 25 are made up of, for example, n-channel metal-oxide-semiconductor (MOS) transistors. Hereinafter, the first load is assumed to be a first load transistor and the second load is assumed to be a second load transistor. The first-stage amplifier may be an amplifier that initially amplifies a signal in a receiving system or an amplifier that amplifies the signal at a later stage in the receiving system. The term “first-stage” is used to indicate upstream positioning with respect to a given (subsequent) component.

A gate terminal, a source terminal, and a drain terminal of the first input transistor 21 are coupled to an input terminal 31 to which a single phase signal is input, a ground point, a source terminal of the first load transistor 24, respectively. The drain terminal of the first input transistor 21 is also coupled to a first output terminal 32. The first load transistor 24 is a diode-coupled transistor, and both a gate terminal and a drain terminal of the first load transistor 24 are coupled to an electrical source terminal 34.

A gate terminal of the second input transistor 22 is coupled to the drain terminal of the first input transistor 21 through a capacitor 26. The capacitor 26 has such capacitance that the capacitor 26 provides an open-circuit condition for direct current voltage and provides a short-circuit condition for alternating current voltage. Accordingly, alternating current voltage from the first input transistor 21 is applied to a gate terminal of the second input transistor 22. In other words, the second input transistor 22 is controlled by the output voltage of the first input transistor 21.

A source terminal and a drain terminal of the second input transistor 22 are coupled to the ground point and a source terminal of the second load transistor 25, respectively. The drain terminal of the second input transistor 22 is also coupled to a second output terminal 33. The second load transistor 25, like the first load transistor 24, has a diode-coupled configuration where a gate terminal and a drain terminal are coupled to the electrical source terminal 34. The first load transistor 24, the second input transistor 22, and the second load transistor 25 have substantially the same mutual conductance.

Operation of the single-ended to differential converting apparatus depicted in FIG. 1 is explained. Mutual conductance of the first input transistor 21 is denoted by Gₘ. Mutual conductance of the first load transistor 24, the second input transistor 22, and the second load transistor 25 is denoted by gₘₙ. When the single-ended to differential converting apparatus depicted in FIG. 1 is coupled to the electrical source 10 through the parasitic inductance 11 like the single-ended to differential converting apparatus 9 depicted in FIG. 8, alternating current encountering the parasitic inductance 11 is denoted by i_{ac}, alternating current running through the first input transistor 21 and the first load transistor 24 is denoted by i, and alternating current running through the second input transistor 22 and the second load transistor 25 is denoted by iₓ.

Input voltage for an input terminal 31, output voltage from the first output terminal 32, and output voltage from the second output terminal 33 are denoted by Vᵢₙ, Vₒᵤₜ, and Vₒᵤₜₓ, respectively. Equation (1) below holds with respect to the first input transistor 21. Since load impedance of the first load transistor 24 is 1/gₘₙ, from equation (1), equation (2) below is acquired.

$$\begin{matrix}i = {G}_{m} {V}_{i n} & ( 1 ) \\ {V}_{out} = - i \times \frac{1}{{g}_{mn}} = - {G}_{m} {V}_{i n} \times \frac{1}{{g}_{mn}} & ( 2 )\end{matrix}$$

Since the input voltage of the second input transistor 22 is Vₒᵤₜ, with respect to the second input transistor 22, equation (3) below is acquired with the aid of equation (2). Further, since load impedance of the second load transistor 25 is 1/gₘₙ, equation (4) is acquired with the aid of equation (3).

$$\begin{matrix}{i}_{x} = {g}_{mn} {V}_{out} = - {G}_{m} {V}_{i n} & ( 3 ) \\ {V}_{outx} = - {i}_{x} \times \frac{1}{{g}_{mn}} = {G}_{m} {V}_{i n} \times \frac{1}{{g}_{mn}} & ( 4 )\end{matrix}$$

Since i_{ac} is the sum of i and iₓ, equation (5) below is acquired from equations (1) and (3). Therefore, alternating current i_{ac} does not encounter the parasitic inductance 11 of FIG. 8. Further, equation (6) below is acquired from equations (2) and (4). Therefore, differential signals of substantially the same magnitude, the phase of one of the signals being inverted, are output from the first output terminal 32 and the second output terminal 33.

i_{ac}=i+iₓ=0 (5)

Vₒᵤₜ=−Vₒᵤₜₓ (6)

FIG. 2 is a circuit diagram of a single-ended to differential converting apparatus according to a second embodiment. As depicted in FIG. 2, the single-ended to differential converting apparatus according to the second embodiment includes the first load transistor, the second input transistor, and the second load transistor that are made up of p-channel MOS transistors.

The gate terminal and the source terminal of the first input transistor 21 are coupled to the input terminal 31 and the ground point, respectively. The drain terminal of the first input transistor 21 is coupled to both a drain terminal of a first load transistor 44 and the first output terminal 32. The first load transistor 44 has the diode-coupled configuration where a gate terminal is coupled to a drain terminal. A source terminal of the first load transistor 44 is coupled to the electrical source terminal 34.

A gate terminal of the second input transistor 42 is coupled to the drain terminal of the first input transistor 21 through the capacitor 26. A source terminal and a drain terminal of the second input transistor 42 are coupled to the electrical source terminal 34 and a source terminal of a second load transistor 45, respectively. The drain terminal of the second input transistor 42 is also coupled to the second output terminal 33. A second load transistor 45 has a diode-coupled configuration where a gate terminal and a drain terminal are coupled to the ground point. The first load transistor 44, the second input transistor 42, and the second load transistor 45 have substantially the same mutual conductance.

The single-ended to differential converting apparatus depicted in FIG. 2 operates as explained in the first embodiment. However, mutual conductance of the first load transistor 44, the second input transistor 42, and the second load transistor 45 is denoted by gₘₚ, and gₘₙ in equation (2) to (4) is replaced with gₘₚ. Therefore, also according to the second embodiment, alternating current i_{ac} does not encounter such parasitic inductance 11 as described with respect to FIG. 8. Further, differential signals of substantially the same magnitude, the phase of one of the signals being inverted, are output from the first output terminal 32 and the second output terminal 33.

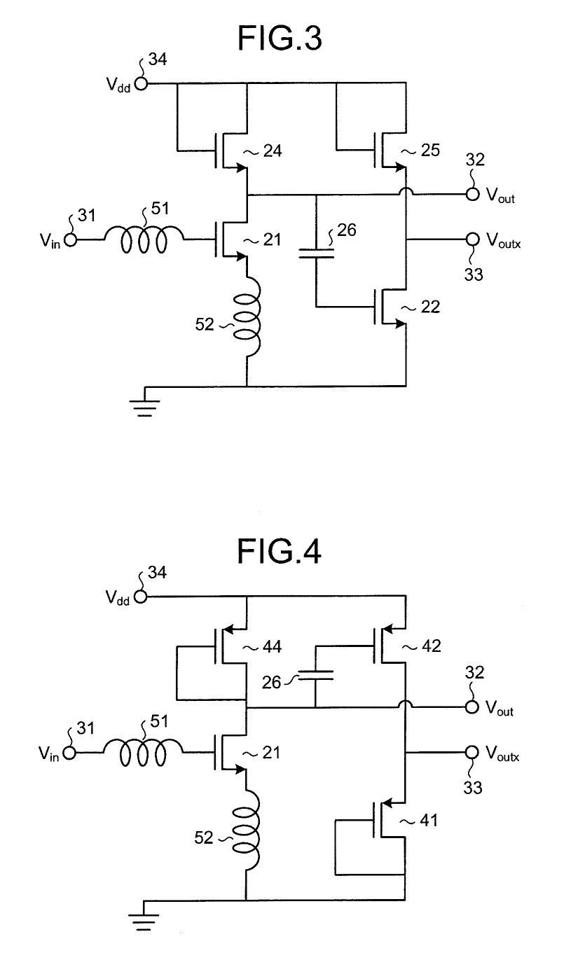

FIG. 3 is a circuit diagram of a single-ended to differential converting apparatus according to a third embodiment. As depicted in FIG. 3, the single-ended to differential converting apparatus according to the third embodiment includes, compared with the single-ended to differential converting apparatus according to the first embodiment, a first inductor 51 between the gate terminal of the first input transistor 21 and the input terminal 31, and a second inductor 52 between the source terminal of the first input transistor 21 and the ground point. Adjustment of inductance of the inductors 51 and 52 makes input impedance of the first input transistor 21 match output impedance of an upstream circuit that outputs a signal to the single-ended to differential converting apparatus; for example, 50Ω. Accordingly, the single-ended to differential converting apparatus according to the third embodiment further possesses a function of low noise amplifier (LNA); namely, the single-ended to differential converting apparatus according to the third embodiment may be used as an LNA.

FIG. 4 is a circuit diagram of a single-ended to differential converting apparatus according to a fourth embodiment. As depicted in FIG. 4, the single-ended to differential converting apparatus according to the fourth embodiment includes the first inductor 51 between the gate terminal of the first input transistor 21 and the input terminal 31, and the second inductor 52 between the source terminal of the first input transistor 21 and the ground point. In this way, as explained in the third embodiment, the single-ended to differential converting apparatus according to the fourth embodiment may be used as an LNA.

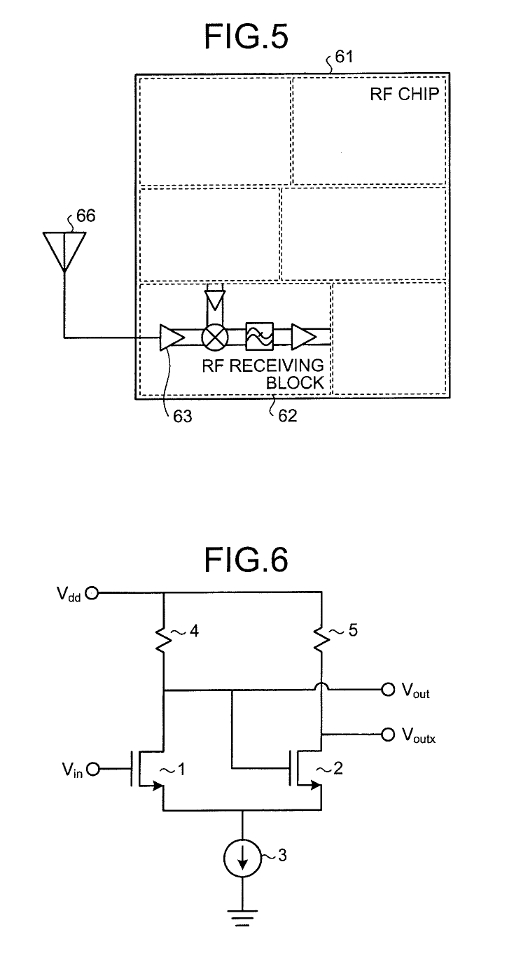

FIG. 5 is a diagram of an RF receiving apparatus according to a fifth embodiment. As depicted in FIG. 5, a radio frequency (RF) chip 61 of the RF receiving apparatus has regions divided as function blocks. One of the function blocks is an RF receiving block 62. The RF chip 61 also includes a single-ended to differential converting apparatus 63 according to one of the first to the fourth embodiments. In the figure, the single-ended to differential converting apparatus 63 is included in the RF receiving block 62 but may be disposed outside the RF receiving block 62. An input terminal of the single-ended to differential converting apparatus 63 is coupled to an antenna 66 extending outward from the RF chip 61. Accordingly, the single-ended to differential converting apparatus 63 converts a single phase signal incoming through the antenna 66 into a differential signal that is suitable for processing in the RF receiving block 62.

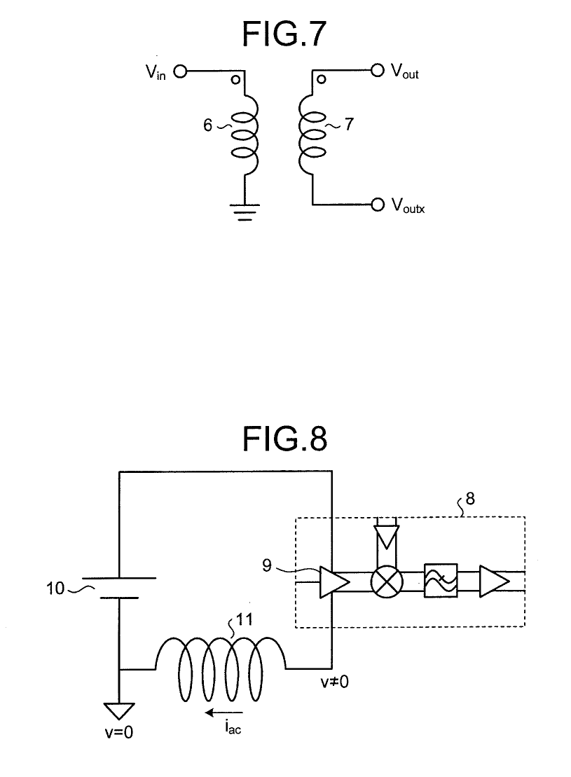

According to the first to the fourth embodiments, alternating current i_{ac} becomes zero throughout the single-ended to differential converting apparatus even without a constant current source. As a result, the constant current source is not needed in the single-ended to differential converting apparatus; whereby the dynamic range of output voltage may be expanded to substantially the same extent as source voltage V_{dd}. Further, large size inductors as depicted in FIG. 7 may be no longer necessary; whereby the size of single-ended to differential converting apparatus becomes about 40 μm×40 μm, facilitating integration in an IC chip. Therefore, as explained in the fifth embodiment, an IC chip such as an RF chip including a single-ended to differential converting apparatus is obtained.

As set forth above, a single-ended to differential converting apparatus according to the embodiments may output a differential signal having a wide dynamic range. The single-ended to differential converting apparatus may be integrated in an IC chip.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A single-ended to differential converting apparatus comprising:
a first amplifier configured to output a first voltage signal corresponding to a single phase input signal; and
a second amplifier configured to output a second voltage signal corresponding to the first voltage signal,
wherein a first load of the first amplifier, an input transistor of the second amplifier, and a second load of the second amplifier have identical mutual conductance.

2. The single-ended to differential converting apparatus according to claim 1, wherein the input transistor is an re-channel transistor, and the first load and the second load are diode-coupled n-channel transistors.

3. The single-ended to differential converting apparatus according to claim 1, wherein the input transistor is a p-channel transistor, and the first load and the second load are diode-coupled p-channel transistors.

4. The single-ended to differential converting apparatus according to claim 1, wherein a capacitor is provided between an output terminal of the first amplifier and an input terminal of the second amplifier, and works as an open circuit for direct current and works as a short circuit for alternating current.

5. The single-ended to differential converting apparatus according to claim 1, wherein a first inductor is coupled to an input terminal of the first amplifier, and a second inductor is provided between the first amplifier and a ground.

6. The single-ended to differential converting apparatus according to claim 5, wherein input impedance of the first amplifier matches output impedance of an upstream circuit.

7. A RF receiving apparatus comprising:
a single-ended to differential converting apparatus including:
a first amplifier configured to output a first voltage signal corresponding to a single phase input signal; and
a second amplifier configured to output a second voltage signal corresponding to the first voltage signal,
wherein a load of the first amplifier, an input transistor of the second amplifier, and a load of the second amplifier have identical mutual conductance; and
a RF receiving block configured to process a differential signal output from the single-ended to differential converting apparatus.

8. The RF receiving apparatus according to claim 7, wherein the input transistor is an n-channel transistor, and the first load and the second load are diode-coupled re-channel transistors.

9. The RF receiving apparatus according to claim 7, wherein the input transistor is a p-channel transistor, and the first load and the second load are diode-coupled p-channel transistors.

10. The RF receiving apparatus according to claim 7, wherein a capacitor is provided between an output terminal of the first amplifier and an input terminal of the second amplifier, and works as an open circuit for direct current and works as a short circuit for alternating current.

11. The RF receiving apparatus according to claim 7, wherein a first inductor is coupled to an input terminal of the first amplifier, and a second inductor is provided between the first amplifier and a ground.

12. The RF receiving apparatus according to claim 11, wherein input impedance of the first amplifier matches output impedance of an upstream circuit.
